(19) United States
(12) Patent Application Publication
(10) Pub. No.: US 2025/0271781 A1
(43) Pub. Date: Aug. 28, 2025

(54) ASSEMBLY FOR AN OPTICAL SYSTEM

(71) Applicant: Carl Zeiss SMT GmbH, Oberkochen (DE)

(72) Inventors: Thomas WOLFSTEINER, Aalen (DE); Stefan WALZ, Schwaebisch Gmuend (DE); Markus HOLZ, Aalen (DE); Hermann BIEG, Huettlingen (DE); Andreas-Josef GRIMM, Rainau (DE); Andreas FROMMEYER, Schwaebisch Gmuend (DE)

(21) Appl. No.: 19/205,166

(22) Filed: May 12, 2025

Related U.S. Application Data
(63) Continuation of application No. PCT/EP2023/079311, filed on Oct. 20, 2023.

(30) Foreign Application Priority Data
Nov. 18, 2022 (DE) 10 2022 212 277.1

(51) Int. Cl. G03F 7/00

(52) U.S. Cl. CPC G03F 7/70891; G03F 7/70316

(57) ABSTRACT

An assembly for an optical system having a mirror array having a plurality of mirror elements arranged on a first carrier. The first carrier contains control leads to the mirror elements. A first heat transport path can dissipate heat from the mirror array to a cooling mechanism during the operation of the optical system. At least one second heat transport path dissipates heat from the mirror array to a cooling mechanism during the operation of the optical system. The first heat transport path and the at least one second heat transport path are spatially separated from one another at least in regions. The first heat transport path extends via an interface component. The first heat transport path extends via the first carrier and the interface component from the mirror array to a cooling mechanism surrounding the interface component.

### CROSS-REFERENCE TO RELATED APPLICATIONS

The present application is a continuation of, and claims benefit under 35 USC 120 to, international application No. PCT/EP2023/079311, filed Oct. 20, 2023, which claims benefit under 35 USC 119 of German Application No. 10 2022 212 277.1, filed Nov. 18, 2022. The entire disclosure of each of these applications is incorporated by reference herein.

### FIELD

The disclosure relates to an assembly for an optical system.

### BACKGROUND

Microlithography is used for producing microstructured components, such as integrated circuits or LCDs, for example. The microlithography process is performed in what is known as a projection exposure apparatus comprising an illumination device and a projection lens. The image of a mask (=reticle) illuminated via the illumination device is in this case projected via the projection lens onto a substrate (e.g. a silicon wafer) coated with a light-sensitive layer (photoresist) and arranged in the image plane of the projection lens, in order to transfer the mask structure to the light-sensitive coating on the substrate.

In projection lenses designed for the EUV range, for example, at wavelengths of approximately 13.5 nm or less, mirrors are used as optical components for the imaging process owing to the general lack of availability of suitable light-transmissive refractive materials.

In the illumination device of a microlithographic projection exposure apparatus designed for operation in the EUV, the use of facet mirrors in the form of field facet mirrors and pupil facet mirrors as focusing components is known for example from DE 10 2008 009 600 A1. Facet mirrors of this type are constructed from a large number of mirror elements or mirror facets, which can each be designed to be tiltable via flexures for the purpose of adjustment or also for implementing specific illumination angle distributions. These mirror facets may comprise a plurality of micromirrors in turn. Moreover, the use of mirror arrangements which comprise a multiplicity of mutually independently adjustable micromirrors in an illumination device of a microlithographic projection exposure apparatus, designed for operation at wavelengths in the VUV range, for setting defined illumination settings (i.e. intensity distributions in a pupil plane of the illumination device) is also known, e.g. from WO 2005/026843 A2.

In practice, as a result inter alia of absorption of the radiation emitted by the EUV light source, the EUV mirrors or mirror elements can heat up and undergo an associated thermal expansion or deformation, which in turn can result in an impairment of the imaging properties of the optical system. Additionally, parasitic heat also can emanate from electronic components provided for controlling the mirror elements. Various approaches, such as active direct cooling of the mirrors or mirror elements, are known in relation to avoiding surface deformations caused by heat inputs into an EUV mirror and optical aberrations associated therewith.

In practice, with active cooling of the aforementioned mirrors or mirror elements, with increasing power of the light source, the achievement of sufficiently efficient heat dissipation while still ensuring high precision of the mirrors or mirror elements can represent a demanding challenge. In this context, for example, the heat dissipation might take place in a manner ensuring the tightness used to maintain the vacuum conditions in the surroundings of the mirror array, wherein, simultaneously, the electrical leads used to control the mirror elements are to be guided to the mirror arrangement from an electronic control arrangement situated outside of this vacuum in the ambient or clean room atmosphere.

The assembly to be provided here for the mechanical mounting and control of the mirror array typically has great sensitivity to deformations, inasmuch as a thermally induced deformation accompanying the heating of the mirror elements due to incident electromagnetic radiation, and also the parasitic heat of the electronic components, ultimately leads to a tilt of the mirror elements and hence leads to optical aberrations, whereby the performance of the optical system or the projection exposure apparatus can be impaired.

Reference is made merely by way of example to DE 10 2012 200 733 A1, DE 10 2014 203 144 A1 and U.S. Pat. No. 9,658,542 B2.

### SUMMARY

The present disclosure seeks to provide an assembly for an optical system which even in the event of high thermal loads allows effective avoidance of thermally induced deformations of a mirror array present in the assembly and simultaneously ensures positional accuracy of the mirror elements.

According to an aspect, the disclosure provides an assembly for an optical system comprising:
a mirror array having a plurality of mirror elements arranged on a first carrier, the latter containing control leads to the mirror elements;
a first heat transport path by which heat can be dissipated from the mirror array to a cooling mechanism during the operation of the optical system; and
at least one second heat transport path by which heat can be dissipated from the mirror array to a cooling mechanism during the operation of the optical system,
wherein the first heat transport path and the at least one second heat transport path are spatially separated from one another at least in regions,
wherein the first heat transport path extends via an interface component, and
wherein the first heat transport path extends via the first carrier and the interface component from the mirror array to a cooling mechanism surrounding the interface component.

Within the meaning of the present application, the term “heat transport path” should be understood in the sense that the heat transport is not further restricted in relation to the underlying functional principle. Thus, for example, the functional principle may be based on thermal conduction, convection, the use of a phase transition (e.g. corresponding to a heat pipe) or else a cooling fluid flow.

For example, the first heat transport path and the at least one second heat transport path may in the process have different functional principles in relation to heat dissipation (and so for example the one heat transport path may utilize thermal conduction, and the other heat transport path may utilize a phase transition).

A connection between the mirror elements and the first carrier may be mechanical and/or else electrical and may be formed, e.g., by soldering, adhesive bonding (e.g. using an electrically conductive adhesive) or by way of other joining methods. The first carrier may also be embodied as a printed circuit board, wherein this printed circuit board may comprise a plurality of layers and wherein contacting of the individual layers via vias may be provided for. Moreover, a vacuum tightness may also be established by way of the first carrier.

For example, the disclosure involves a concept of providing, in an assembly comprising a mirror array having a plurality of mirror elements, at least two mutually separate heat transport paths for the purpose of dissipating heat that accumulates during the operation of the assembly or of the associated optical system-both as a consequence of incident electromagnetic radiation and as a consequence of electromagnetic power losses in electronic components present. In comparison with a conventional assembly having only one heat transport path, the disclosure deliberately accepts an increased constructional outlay and also a greater installation space in order, in return, to obtain increased capability of the assembly in view of thermal loads that result from incident electromagnetic radiation (e.g. EUV light) and power losses of the electronics used for example for controlling the mirror elements in the mirror arrangement.

According to an embodiment, the interface component is produced from a material with a thermal conductivity of at least 10 W/(m·K), such as at least 150 W/(m·K), and for example at least 400 W/(m·K). For example, high-alloy steel with a thermal conductivity of approximately 13 W/(m·K) may be used as material. However, the disclosure is not restricted thereto, wherein materials with a lower thermal conductivity or optionally even with a substantially higher thermal conductivity (e.g., of up to 5000 W/(m·K) as in the case of graphene, for example) may also be usable.

According to an embodiment, the second heat transport path also extends via the interface component.

According to an embodiment, the first heat transport path extends via the first carrier and the interface component from the mirror array to a cooling mechanism surrounding the interface component. In this context, the interface component and the cooling mechanism surrounding it may be separated from one another by a gap in embodiments.

In an aspect, the disclosure provides an assembly for an optical system comprising:
a mirror array having a plurality of mirror elements arranged on a first carrier, the latter containing control leads to the mirror elements;
a first heat transport path by which heat can be dissipated from the mirror array to a cooling mechanism during the operation of the optical system; and
at least one second heat transport path by which heat can be dissipated from the mirror array to a cooling mechanism during the operation of the optical system,
wherein the first heat transport path and the at least one second heat transport path are spatially separated from one another at least in regions.

According to the disclosure, the first heat transport path may extend via an interface component which is produced from a material with a thermal conductivity of at least 10 W/(m·K), such as 150 W/(m·K), for example at least 400 W/(m·K).

According to an embodiment, the at least one second heat transport path extends via the first carrier and the interface component from the mirror array to a cooling mechanism. For example, this may be a second cooling mechanism that is spatially separated from the (first) cooling mechanism belonging to the first heat transport path. In addition or in an alternative to the first carrier, the second heat transport path may also extend via a second carrier (yet to be described hereinafter).

Moreover, as described in detail below, the first heat transport path and/or the second heat transport path may also extend via one or more thermal interface materials (TIM=“Thermal Interface Material”).

According to an embodiment, the interface component is secured directly to this cooling mechanism (or to the second cooling mechanism separated from the first cooling mechanism).

According to an embodiment, the assembly comprises a second carrier which mechanically couples the first carrier to the interface component via at least one flexure. For example, effects of a mismatch in the coefficients of thermal expansion (CTE=“Coefficient of Thermal Expansion”) between the materials of the first carrier (a ceramic material, for example) and the interface component (a metallic material such as e.g. copper (Cu), for example) may be reduced or minimized by way of this second carrier and its coupling via the flexure. Moreover, mechanical and/or thermal decoupling may be brought about by way of the flexure.

According to an embodiment, the second carrier is produced from a material with a thermal conductivity of less than 40 W/(m·K). However, the disclosure is not restricted to the use of such a material with a comparatively poor thermal conductivity. Thus, especially in the case of thermal decoupling brought about by way of a flexure, the material for the second carrier may also be a material with good thermal conduction properties (e.g. the same material as in the first carrier as well) in order to help avoid differences in this respect between the respective coefficients of thermal expansion of the materials of the first and the second carrier.

According to an embodiment, a portion of the interface component facing the cooling mechanism of the second heat transport path is decoupled, at least partially in thermal fashion, via a portion of reduced thermal conductivity (e.g. in the form of a flexure) from a portion of the interface component facing the first carrier. For example, as is yet to be described in detail hereinafter, this can help enable a configuration of the at least two separate heat transport paths with separated circuits for the cooling medium (e.g. water) and cooling mechanism optionally operable with different temperatures of the cooling medium.

According to an embodiment, the interface component is mechanically decoupled from the cooling mechanism of the second heat transport path via at least one decoupling element.

According to an embodiment, the at least one second heat transport path extends via at least one heat pipe. This heat pipe may also be connected via one or more thermal interface materials (TIMs).

According to an embodiment, a thermal resistance of this heat pipe is variably adjustable.

According to an embodiment, the at least one heat pipe is directly secured to the cooling mechanism (optionally via one or more thermal interface materials (TIMs)).

According to an embodiment, the first heat transport path and/or the at least one second heat transport path extend through electronic components integrated into the assembly. In this case, tolerance compensation may be obtained by way of thermal interface materials (TIMs) likewise situated in the heat transport path.

According to an embodiment, a common cooling mechanism is provided in the first heat transport path and in the second heat transport path.

According to an embodiment, cooling mechanisms that are separated from one another are provided in the first heat transport path and in the second heat transport path.

According to an embodiment, cooling media of these cooling mechanisms can be set to temperatures that differ from one another.

According to an embodiment, at least one flexure designed with a decoupling geometry for partial mechanical decoupling is arranged between the first carrier and the second carrier and/or between the second carrier and the interface component.

According to an embodiment, a vacuum atmosphere present in the surroundings of the mirror array is separated (for example using sealing elements) from a non-vacuum atmosphere present in the surroundings of the cooling mechanism of the first heat transport path and in the surroundings of the cooling mechanism of the second heat transport path.

According to an embodiment, the mirror array is designed for an operating wavelength of less than 30 nm, such as less than 15 nm.

The disclosure also relates to an optical system, for example of a microlithographic projection exposure apparatus, having an assembly with the above-described features, and also to a microlithographic projection exposure apparatus having such an optical system.

Further configurations of the disclosure can be gathered from the description and the claims.

The disclosure is elucidated in detail hereinafter with reference to exemplary embodiments shown in the appended figures.

### BRIEF DESCRIPTION OF THE DRAWINGS

In the figures:

FIGS. 1 and 2A show schematic illustrations of an assembly of an optical system;

FIGS. 2B-7 show schematic illustrations of embodiments of an assembly; and

FIG. 8 shows a schematic illustration of a possible structure of a microlithographic projection exposure apparatus designed for operation in the EUV.

### DETAILED DESCRIPTION

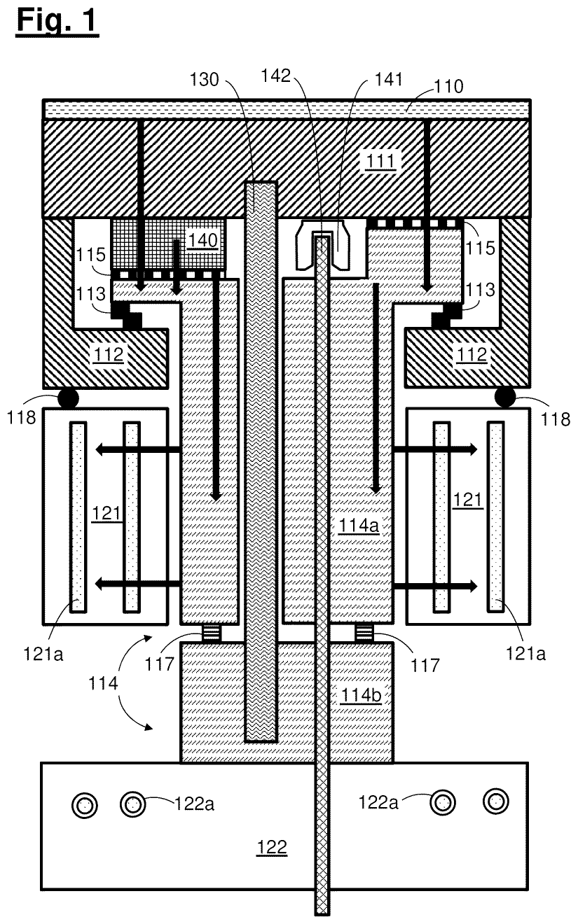

Hereinafter, embodiments of an assembly according to the disclosure for an optical system are described with reference to the schematic illustrations of FIGS. 1-7, wherein the assembly comprises a mirror array having a plurality of mirror elements. What is common to these embodiments is that heat accumulating during the operation of the assembly or of the associated optical system-both as a consequence of the electromagnetic radiation incident on the mirror array and as a consequence of electrical power losses in the electronic components present—can be dissipated to at least one cooling mechanism via at least two heat transport paths that are separate from one another.

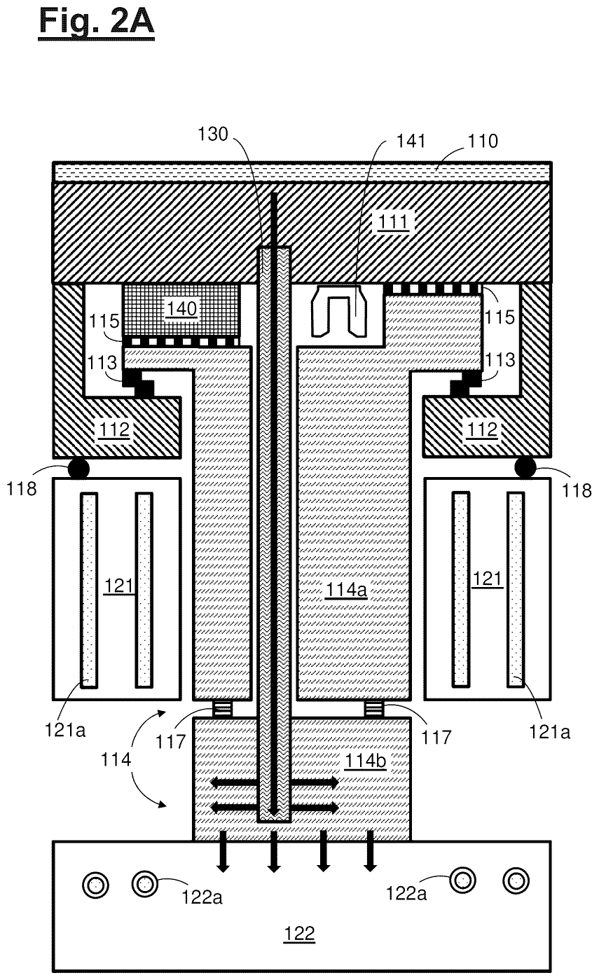

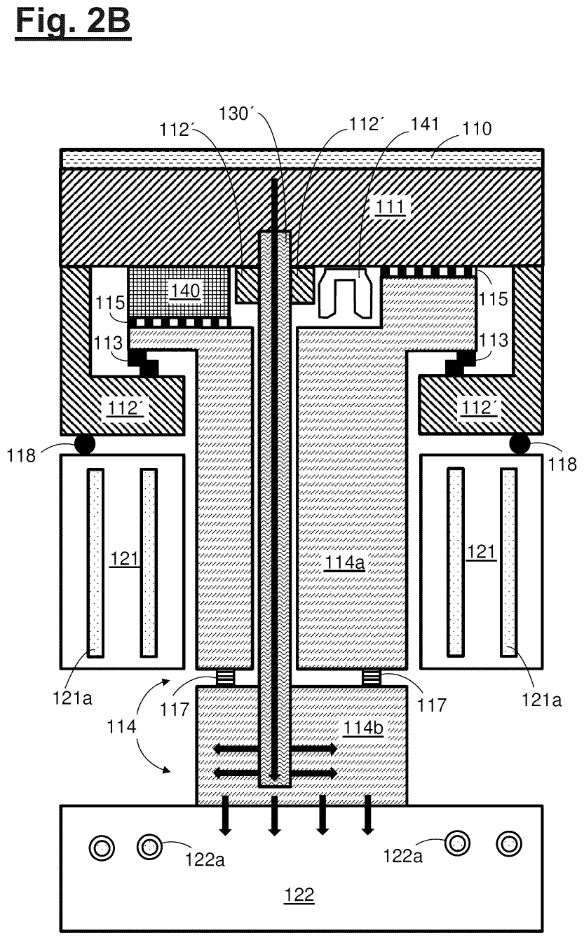

FIGS. 1 and 2A initially show schematic illustrations for explaining the possible structure of an assembly according to the disclosure and of the aforementioned principle that underlies the disclosure, in a first embodiment.

According to FIGS. 1 and 2A, a mirror array 110 is secured to a carrier 111. The material of the carrier 111 may be a ceramic material of comparatively good thermal conductivity (e.g. greater than 100 W/(m·K)) (without the disclosure being restricted thereto), e.g. an aluminum nitride ceramic with a thermal conductivity of approximately 170 W/(m·K). The mirror array 110 comprises a plurality of mirror elements in the form of microelectromechanical systems (known as “MEMS mirrors”), which have not been depicted in detail in FIG. 1 for the sake of simplicity and the respective mirrors of which are designed to be independently adjustable by way of actuators (likewise not depicted in FIG. 1) in a manner known per se, for the purpose of which corresponding electrical leads (not depicted in FIGS. 1 and 2A) are guided through the carrier 111 to the mirror array 110. Both here and in the further embodiments, the carrier 111 may also be a circuit board with different electrical layers and contacts (vias). In this case, the vias are arranged such that the carrier 111 has a vacuum-tight design.

The assembly further comprises an interface component 114, which is produced from a thermally conductive material such as e.g. copper (Cu). In the exemplary embodiment of FIGS. 1 and 2A (without the disclosure being restricted thereto), the interface component 114 comprises two portions 114a, 114b, between which, once again optionally for partial thermal decoupling of these portions from one another, a portion 117 of reduced thermal conductivity (which in this respect may also be referred to as “thermal joint” or as flexure which both thermally and mechanically decouples the portion 114b from the portion 114a by way of a cross section attenuation) is arranged.

The thermal coupling of the interface component 114 to the carrier 111 can be implemented by way of a thermal interface material (TIM= “Thermal Interface Material”) 115, wherein this interface material may be configured as a (thermally conductive) paste, thermally conductive pad, adhesive, film, etc. merely by way of example.

Moreover, the assembly according to FIGS. 1 and 2A comprises a second carrier 112. A mechanical connection of this second carrier 112 to the interface component 114 is implemented by way of a flexure 113, by which at least partial mechanical and thermal decoupling is brought about for the purpose of avoiding or reducing a transfer of mechanical stresses. Moreover, the thermal resistance is also preferably increased by way of the flexure 113, with the result that there is no thermal dissipation (or only very much reduced thermal dissipation) via the second carrier 112. As a consequence of the thermal decoupling brought about by way of the flexure 113, the material for the second carrier 112 need not be a material with comparatively poor thermal conductivity, and so e.g. in this respect it is also possible to use the same material as for the first carrier 111 (for example an aluminum nitride ceramic) in order in this respect to avoid differences between the respective coefficients of thermal expansion of the materials of the first and the second carrier. By way of the flexure 113, it is possible to avoid or reduce deformations as a consequence of the difference present between the respective coefficients of thermal expansion (i.e. a “CTE mismatch”; CTE= “Coefficient of Thermal Expansion”) of the material of the second carrier 112 (e.g. ceramic) and of the material of the interface component 114 (e.g. copper).

However, the disclosure is not restricted thereto. Instead, the second carrier may also be produced from a material with comparatively poor thermal conductivity (e.g. an aluminum oxide ceramic with a thermal conductivity of approximately 35 W/(m·K)) in embodiments (for instance, in the event of a lack of decoupling or insufficient decoupling by way of a flexure 113).

According to FIG. 1, a first heat transport path extends via the carrier 111 and the interface component 114 from the mirror array 110 to a first cooling mechanism 121 that surrounds the interface component 114 (or its first portion 114a) and is also separated from the latter by a gap. There are no further restrictions placed on the disclosure in respect of the specific configuration of this cooling mechanism 121, wherein FIGS. 1 and 2A merely indicate by way of example cooling channels 121a through which a cooling fluid (e.g. cooling water) may flow. The first heat transport path may also extend via one or more electronic components, wherein an electronic component 140 attached to the carrier 111 is depicted merely by way of example in FIGS. 1 and 2A. The electronic component 140 may have (in a manner comparable to a circuit board) electrical connections to the first carrier 111. As indicated, thermal interface material (TIM) 115 may also be provided between this electronic component 140 and the interface component 114 (or the first portion 114a thereof) for an improved thermal coupling.

In the assembly according to FIGS. 1 and 2A, a second heat transport path, which is separate from the first heat transport path, extends in addition to the latter from the mirror array 110 and the carrier 111 to a second cooling mechanism 122 (which e.g. likewise comprises cooling channels 122a through which cooling fluid may flow), wherein this second heat transport path extends via at least one heat pipe 130 (without the disclosure being restricted thereto). According to FIGS. 2A and 2B, this heat pipe 130 is inserted into a drilled hole within the carrier 111 and extends into the second portion 114b of the interface component 114, wherein the fixation of the heat pipe 130, both to the carrier 111 and to the interface component 114 or its second portion 114b, may once again be implemented by way of thermal interface materials (not depicted here) for the purpose of improving the thermal transition. In an alternative to that or in addition, the heat pipe 130 may also be attached in the second carrier 112. For example, this may be advantageous should the carrier 111 have an embodiment that is too thin to allow the condenser of the heat pipe 130 to be connected. In further embodiments, it is also possible to provide for a plurality of heat pipes 130 for realizing the second heat transport path. Furthermore, the heat pipe 130 in further embodiments may also be fixed directly to the cooling mechanism 122 (i.e. without in this respect involving thermal transition points or thermal interface materials within the interface component).

The disclosure is not restricted to the use, depicted in FIG. 2A, of one or more heat pipes 130 for providing the second heat transport path. In further embodiments, the second heat transport path may also be realized as a serial heat transport path by the heat conduction present in the carrier 111 and the components mechanically connected thereto.

In FIG. 1, “142” denotes a printed circuit board, by which the carrier 111 and the electrical leads situated therein are electrically connected to appropriate control electronics (not depicted), wherein an interchange of the printed circuit board 142 without exchanging the entire unit of mirror array 110 and carrier 111 is rendered possible in the exemplary embodiment by the use of a plug-in connector 141.

As depicted by the arrows plotted in the horizontal and vertical direction in FIGS. 1 and 2A, heat accumulating during the operation of the assembly or of the associated optical system-both as a consequence of the electromagnetic radiation incident on the mirror array 110 and as a consequence of electrical power losses in the electronic components present—is firstly transmitted according to FIG. 1 along the first heat transport path via the carrier 111 and the interface component 114, or the first portion 114a thereof, from the mirror array 110 to the first cooling mechanism 121 and is secondly guided along the second heat transport path via the carrier 111 and the heat pipe 130 from the mirror array 110 into the second portion 114b of the interface component 114 and transferred from the latter to the second cooling mechanism 122.

The portion 114b of the interface component 114 facing the cooling mechanism 122 may be directly secured (e.g. screwed) to the cooling mechanism 122 for the purpose of providing the best possible thermal transition and may be thermally decoupled from the first portion 114a of the interface component 114 via the portion 117 of reduced thermal conduction (“thermal joint” or flexure). As a consequence of this thermal decoupling, e.g. comparatively lower temperatures may be realized on part of the cooling mechanism 122 without these leading to a deformation of the mirror elements of the mirror array 110.

As a consequence of the configuration of the first and second heat transport paths with different separate cooling mechanism 121, 122, these cooling mechanism 121, 122 may be operated at temperatures that differ from one another, wherein depending on the specific use scenario the temperature of the second cooling mechanism 122 may be chosen to be higher or else lower than the temperature of the first cooling mechanism 121. For example, this makes it possible to take account of the circumstances that proper functioning of the heat pipe 130 uses the temperature difference at its two end portions (i.e. the temperature difference between the carrier 111 or 112 and the cooling mechanism 122 or the portion 114b of the interface component 114 facing this cooling mechanism 122 in the exemplary embodiment) to exceed a certain threshold. For example, it may be desirable in some use scenarios for the heat pipe 130 to only be effective once a predetermined temperature is reached on part of the carrier 111, in which case the temperature of the cooling mechanism 122 may then be chosen to be higher than the temperature of the cooling mechanism 121. By contrast, a lower value of the temperature of the cooling mechanism 122 in comparison with the temperature of the cooling mechanism 121 may be advantageous if the heat pipe 130 should be effective at all times or during the entire operation of the assembly.

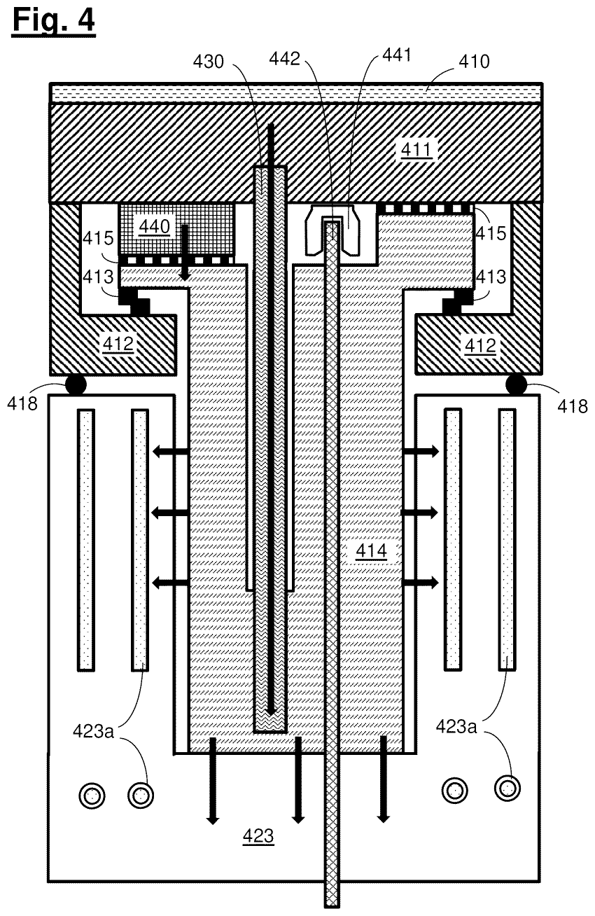

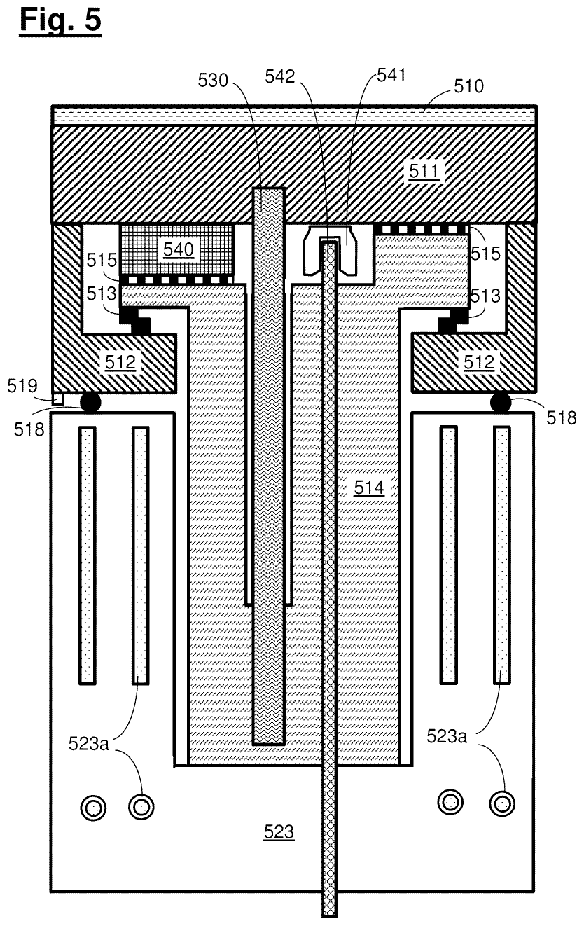

The disclosure is not restricted to the use, described on the basis of FIGS. 1 and 2A, of two separate cooling mechanism 121, 122 in the at least two heat transport paths. For instance—as is yet to be described below on the basis of FIG. 4 and FIG. 5—some embodiments may only provide for a common cooling mechanism for the at least two heat transport paths, wherein the subdivision of the interface component 114 into portions 114a, 114b described above and the thermal decoupling thereof from one another by way of the portion 117 of reduced heat conduction may also be omitted in that case.

FIG. 2B shows a possible modification of the embodiment of FIGS. 1 and 2A, in which the heat pipe (denoted by “130” in FIG. 2B) is also secured to the second carrier (denoted by “112” in FIG. 2B), in addition to being secured to the first carrier 111.

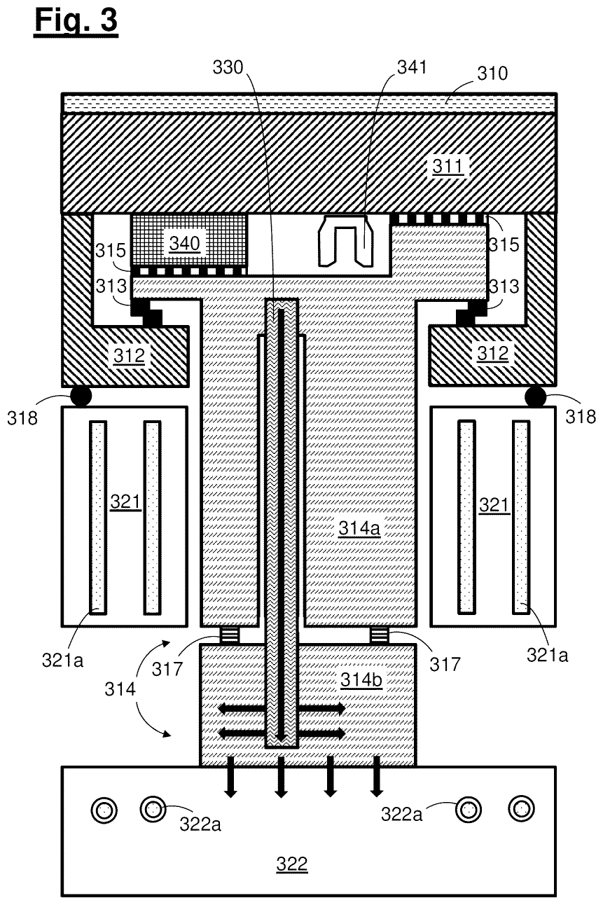

FIG. 3 shows a schematic illustration of a further embodiment of an assembly according to the disclosure, wherein analogous or substantially functionally identical components in comparison with FIGS. 1 and 2A are denoted by reference signs increased by “200”. The embodiment as per FIG. 3 in this case differs from that from FIGS. 1 and 2A in that the heat pipe 330 does not extend up to the carrier 311 but ends in the interface component 314 or the first portion 314a of the latter facing the carrier 311 and is secured there.

FIG. 4 shows, in a schematic illustration, a further embodiment of an assembly according to the disclosure, wherein analogous or substantially functionally identical components in comparison with FIGS. 1 and 2A are denoted by reference signs increased by “300”. As per FIG. 4 and as mentioned previously, only a common cooling mechanism 423, which once again may be configured purely by way of example with respective cooling channels 423a through which a cooling fluid (e.g. cooling water) may flow, is provided for the two above-described heat transport paths. Hence, heat dissipation as per FIG. 4 is implemented via one and the same cooling mechanism 423 both in the first heat transport path from the interface component 414 via the gap remaining toward the cooling mechanism 423 and in the second heat transport path via the heat pipe 430 and the gap-free direct coupling of the interface component 414 to the cooling mechanism 423, and so the respective subdivision of the interface component into portions that are thermally decoupled from one another, in each case depicted on the basis of FIGS. 1-3 above, may also be omitted.

In the configuration with only one cooling mechanism 423—common to both heat transport paths-present as per FIG. 4 as well, the mechanical fixation and thermal coupling to the heat pipe 430 may be implemented within the interface component 414 (rather than the coupling in the carrier 411 and/or 412 depicted in FIG. 4), in a manner analogous to FIG. 3.

FIG. 5 shows a further embodiment of an assembly according to the disclosure, wherein analogous or substantially functionally identical components in comparison with FIG. 4 are denoted by reference signs increased by “100”. The heat conduction according to the disclosure is decoupled from the mechanical positioning as per FIG. 5, in addition to the provision of two separate heat transport paths implemented in a manner analogous to FIG. 4. Hence, as per FIG. 5, the mirror array 510 is mechanically positioned or aligned by way of a thermally non-loaded mechanical positioning path which, in the specific exemplary embodiment, extends from a stop 519, which is provided on the second carrier 512, via the second carrier 512 and the first carrier 511 to the mirror array 510. Hence thermally induced deformations caused in the heat transport paths according to the disclosure do not affect the positioning accuracy or the stability of the mirror elements of the mirror array 511.

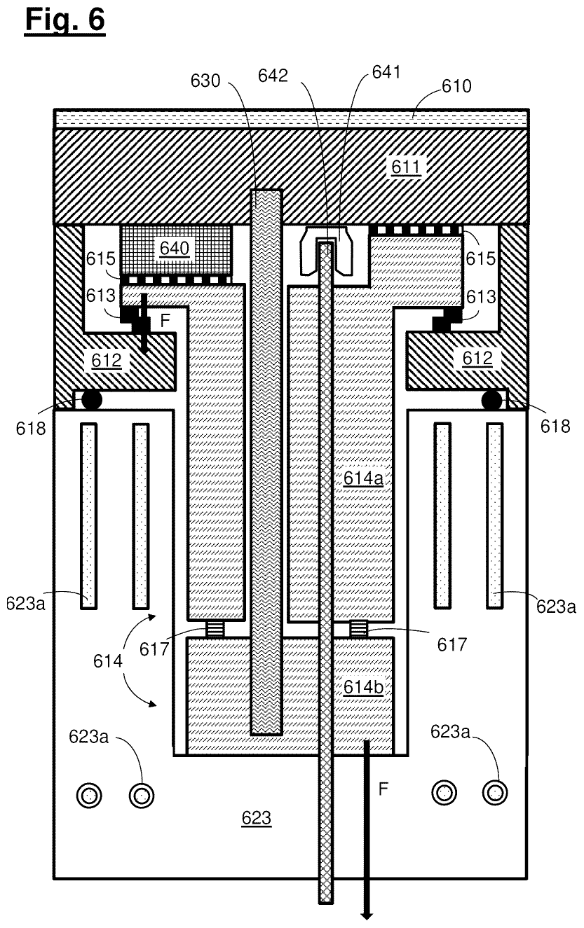

FIG. 6 shows a further embodiment of an assembly according to the disclosure, wherein analogous or substantially functionally identical components in comparison with FIG. 5 are denoted by reference signs increased by “100”. In this case, the joint 617 is designed with sufficient stiffness in the direction that the force is applied, and so the portion 614b may rest against the cooling mechanism 623 as a result of the force F and the force is at the same time large enough to compress the sealing element 618.

According to FIG. 6, the second carrier 612 has a stop surface on the cooling mechanism 623. Mechanical fixation of the second carrier 612 on the first carrier 611 may be implemented by way of a soldered connection, welded connection, adhesively bonded connection or any other joining method. Moreover, mechanical fixation of the second carrier 612 on the interface component 614 or the first portion 614a of the latter may also be implemented by way of a soldered connection, welded connection or adhesively bonded connection. In this case, the flexure 613 serves for partial mechanical and thermal decoupling. A further flexure (not depicted in FIG. 6) may be provided between the second carrier 612 and the cooling mechanism 623 in order to avoid or reduce mechanical overdetermination. A sealing element is denoted by “618” and e.g. compressed when the assembly is screwed together, within the scope of which screwing operation the stop surface of the interface component 614 or the second portion 614b of the latter is secured to the cooling mechanism 623. In this case, the portion 617 designed as a flexure is designed in such a way in the embodiment of FIG. 6 that, firstly, the connection between the second portion 614b of the interface component 614 and the cooling mechanism 623 is rendered possible. At the same time, the portion 617 designed as a flexure is designed to be so stiff that the second carrier 612 may rest against the cooling mechanism 623 and may compress the sealing element 618.

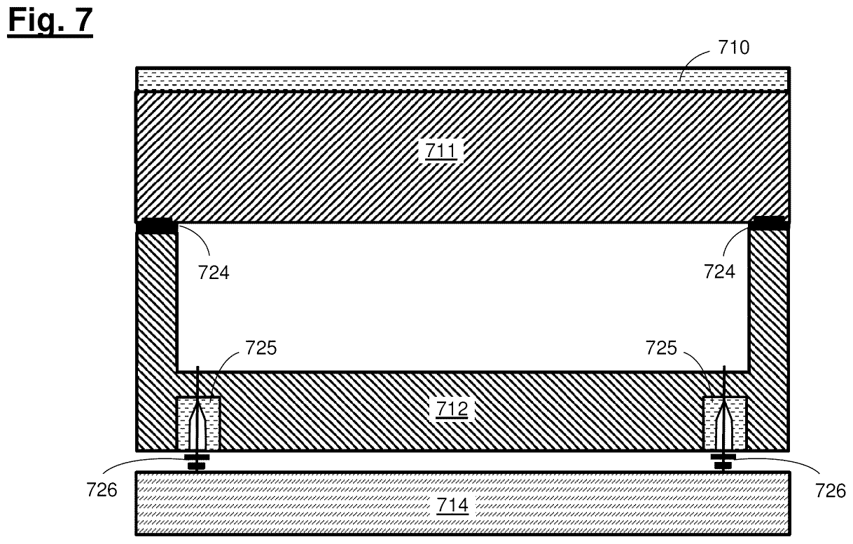

In order to provide a soldered connection between the first carrier 611 and the second carrier 612 should the carrier 611 and/or the carrier 612 be embodied as a ceramic carrier or printed circuit board, the metallic materials used for soldering are already sintered into the respective components in a manner corresponding to the carriers 611, 612. The decoupling geometry suitable for providing the flexure serving mechanical decoupling purposes may also be created in the process. To illustrate this, FIG. 7 shows a schematic illustration of a detailed view, wherein components that are analogous or substantially functionally identical in comparison with FIG. 6 are denoted by reference signs increased by “100”. Solder joints between the first carrier 711 and the second carrier 712 are denoted by “724”. In this case, a flexure may likewise be formed in the mechanical connection between the first carrier 711 and the second carrier 712 and said flexure may in turn be integrated in the respective sintered metallic materials or regions already found on part of the first carrier 711 and/or on part of the second carrier 712 (by forming an appropriate decoupling geometry). Metallic inserts for threads are denoted by “725”. Should the second carrier 712 be produced from ceramic material, these inserts 725 may be sintered (and otherwise also be adhesively bonded). A decoupling element for thermal and/or mechanical decoupling is denoted by “726” in each case.

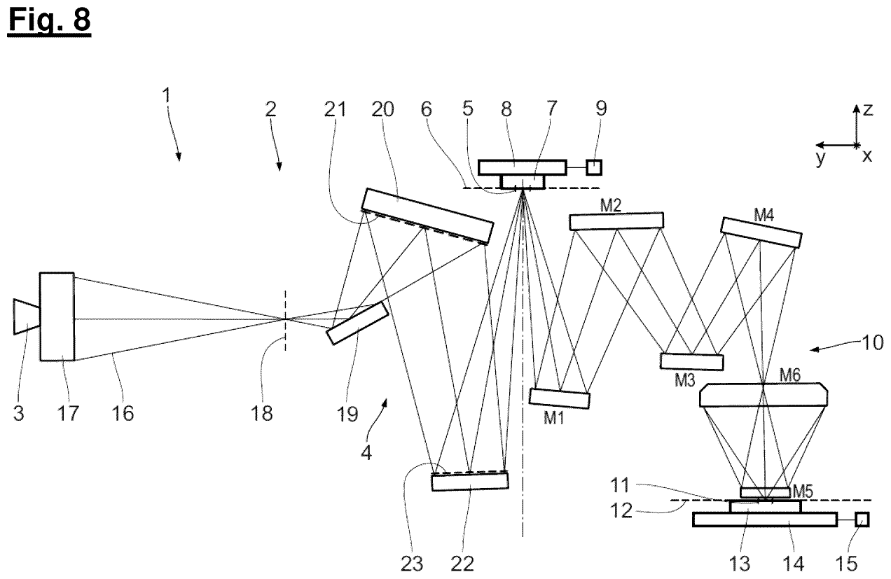

FIG. 8 schematically shows a meridional plane of the possible structure of a microlithographic projection exposure apparatus, which is designed for operation in the EUV and in which the disclosure is realizable by way of example.

According to FIG. 8, the projection exposure apparatus 1 comprises an illumination device 2 and a projection lens 10. One embodiment of the illumination device 2 of the projection exposure apparatus 1 has, in addition to a light or radiation source 3, an illumination optics unit 4 for illuminating an object field 5 in an object plane 6. In an alternative embodiment, the light source 3 may also be provided as a module separate from the rest of the illumination device. In this case, the illumination device does not comprise the light source 3.

What is exposed here is a reticle 7 arranged in the object field 5. The reticle 7 is held by a reticle holder 8. The reticle holder 8 is displaceable by way of a reticle displacement drive 9, for example in a scanning direction. For explanatory purposes, a Cartesian xyz-coordinate system is depicted in FIG. 8. The x-direction runs perpendicularly to the plane of the drawing into the latter. The y-direction runs horizontally, and the z-direction runs vertically. The scanning direction runs in the y-direction in FIG. 8. The z-direction runs perpendicularly to the object plane 6.

The projection lens 10 serves for imaging the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction. The displacement, firstly, of the reticle 7 by way of the reticle displacement drive 9 and, secondly, of the wafer 13 by way of the wafer displacement drive 15 may be synchronized with one another.

The radiation source 3 is an EUV radiation source. The radiation source 3 emits EUV radiation, which is also referred to below as used radiation or illumination radiation. For example, the used radiation has a wavelength in the range of between 5 nm and 30 nm. The radiation source 3 can be for example a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optics unit 4. The illumination optics unit 4 comprises a deflection mirror 19 and, arranged downstream thereof in the beam path, a first facet mirror 20 (having schematically indicated facets 21) and a second facet mirror 22 (having schematically indicated facets 23). For example, these facet mirrors may be realized in the manner of the disclosure.

The projection lens 10 comprises a plurality of mirrors Mi (i=1, 2, . . . ), which are consecutively numbered according to their arrangement in the beam path of the projection exposure apparatus 1. In the example illustrated in FIG. 8, the projection lens comprises six mirrors M1 to M6. Alternatives with four, eight, ten, twelve or a different number of mirrors Mi are also possible. The penultimate mirror M5 and the last mirror M6 each have a through opening for the illumination radiation 16. The projection lens 10 is a doubly obscured optical unit. The projection lens 10 has an image-side numerical aperture that is greater than 0.5 and may also be greater than 0.6 and may be for example 0.7 or 0.75.

However, the disclosure is not restricted to use in a projection exposure apparatus designed for operation in the EUV. For example, the disclosure can also be advantageously used in a projection exposure apparatus designed for operation in the DUV (i.e. at wavelengths less than 250 nm, such as less than 200 nm) or also in another optical system.

Although the disclosure has also been described via special embodiments, numerous variations and alternative embodiments, e.g. by combining and/or exchanging features of individual embodiments, can be discerned by a person skilled in the art. Accordingly, it is understood by those skilled in the art that such variations and alternative embodiments are also comprised by the present disclosure, and the scope of the disclosure is limited only in the sense of the appended claims and their equivalents.

1. An assembly, comprising:
a mirror array comprising a plurality of MEMS mirrors;
a carrier supporting the mirror array;
an interface component;
a first cooling mechanism surrounding the interface component; and
a second cooling mechanism,
wherein:
the assembly comprises a first heat transport path which is configured to dissipate heat from the mirror array to the first cooling mechanism;
the first heat path comprises the first carrier and the interface component;
the assembly comprises a second heat transport path which is configured to dissipate heat from the mirror array to the second cooling mechanism;
the first and second heat transport paths are spatially separated from each other at least in regions; and
the first heat transport path is around an exterior of the second heat transport path.

2. The assembly of claim 1, wherein the first heat transport path dissipates heat in a first manner, and the second heat transport path dissipates heat in a second manner different from the first manner.

3. The assembly of claim 1, wherein the interface component comprises a material having a thermal conductivity of at least 10 Watts per meter-Kelvin.

4. The assembly of claim 1, wherein the second heat transport path comprises the interface component.

5. The assembly of claim 1, wherein the second heat transport path comprises the first carrier and the interface component.

6. The assembly of claim 5, wherein the interface component is directly secured to the second cooling mechanism.

7. The assembly of claim 1, further comprising a second carrier and a flexure, wherein the second carrier mechanically couples the first carrier and the interface component via the flexure.

8. The assembly of claim 7, wherein the second carrier comprises a material having a thermal conductivity of less than 40 Watts per meter-Kelvin.

9. The assembly of claim 1, wherein:
a first portion of the interface component faces the first carrier;
a second portion of the interface component faces the second cooling mechanism;
the second portion of the interface has a lower thermal conductivity than the first portion of the interface component; and
the second portion of the interface is at least partially mechanically decoupled from the first portion of the interface component, and/or the second portion of the interface is at least partially thermally decoupled from the first portion of the interface component.

10. The assembly of claim 1, further comprising a decoupler that mechanically decouples the interface component from the second cooling mechanism.

11. The assembly of claim 1, wherein the second heat transport path comprises a heat pipe.

12. The assembly of claim 11, wherein a thermal resistance of the heat pipe is variably adjustable.

13. The assembly of claim 11, wherein the heat pipe is directly secured to the second cooling mechanism.

14. The assembly of claim 1, further comprising an electronic component, wherein the first heat transport path comprises the electronic component and/or the second heat transport path comprises the electronic component.

15. The assembly of claim 1, further comprising a common cooler, wherein the first and second heat transport paths comprise the common cooler.

16. The assembly of claim 1, wherein portions of the first and second cooling mechanisms that are separated from one each other are provided in the first heat transport path and in the second heat transport path.

17. The assembly of claim 16, wherein the assembly is configured so that cooling media of the first and second cooling mechanisms differ from each other.

18. The assembly of claim 1, further comprising a flexure designed comprising a decoupling geometry, wherein:
the assembly comprises a second carrier, and the flexure is between the first and second carriers; and/or
the flexure is between the second carrier and the interface component.

19. The assembly of claim 1, wherein the assembly is configured to have a vacuum atmosphere in surroundings of the mirror array which is separated from a non-vacuum atmosphere in surroundings of the first and second cooling mechanisms.

20. The assembly of claim 1, wherein the MEMS mirrors are reflective for electromagnetic radiation at a wavelength of less than 30 nanometers.

21. The assembly of claim 1, wherein the support comprises control leads to the MEMS mirrors.

22. An optical system, comprising:
an assembly according to claim 1,
wherein the optical system is a microlithographic projection exposure apparatus.
